(19) United States
(12) Patent Application Publication
(10) Pub. No.: US 2014/0210106 A1
(43) Pub. Date: Jul. 31, 2014

(54) ULTRA THIN PoP PACKAGE

(71) Applicant: APPLE INC., Cupertino, CA (US)

(72) Inventor: Jun Zhai, San Jose, CA (US)

(73) Assignee: APPLE INC., Cupertino, CA (US)

(21) Appl. No.: 13/753,014

(22) Filed: Jan. 29, 2013

(51) Int. Cl. H01L 23/28; H01L 21/56

(52) U.S. Cl. CPC H01L 23/28; H01L 21/56
USPC 257/777; 438/118

(57) ABSTRACT

A PoP (package-on-package) package includes a bottom package coupled to a top package. The bottom package includes a die coupled to an interposer layer with an adhesive layer. One or more terminals are coupled to the interposer layer on the periphery of the die. The terminals and the die are at least partially encapsulated in an encapsulant. The terminals and the die are coupled to a redistribution layer (RDL). Terminals on the bottom of the RDL are used to couple the PoP package to a motherboard or a printed circuit board (PCB). One or more additional terminals couple the interposer layer to the top package. The additional terminals may be located anywhere along the surface of the interposer layer.

### BACKGROUND

1. Field of the Invention

The present invention relates to semiconductor packaging and methods for packaging semiconductor devices. More particularly, the invention relates to a bottom package of a PoP (package-on-package).

2. Description of Related Art

Package-on-package (“PoP”) technology has become increasingly popular as the demand for lower cost, higher performance, increased integrated circuit density, and increased package density continues in the semiconductor industry. As the push for smaller and smaller packages increases, the integration of die and package (e.g., “pre-stacking” or the integration of system on a chip (“SoC”) technology with memory technology) allows for thinner packages. Such pre-stacking has become a critical component for thin and fine pitch PoP packages.

One limitation in reducing the size of a package (e.g., either the top package (the memory package) or the bottom package (the SoC package) in the PoP package) is the size of the substrate used in the package. Thin substrates and/or coreless substrates (e.g., laminate substrates) have been used to reduce the size of the packages to certain levels. Further reductions in size, however, may be needed in order to provide even smaller packages for next generation devices.

A potential problem that arises when reducing the size of the packages is the increasing likelihood of warpage in the package as the package gets thinner and thinner. Warping problems may lead to failure or reduced performance of the PoP package and/or problems in reliability of devices utilizing the PoP package. For example, the differences in warpage behavior between top and bottom packages in the PoP package may cause yield loss in the solder joints coupling the packages. A large fraction of PoP structures may be thrown away (rejected) because of stringent warpage specifications placed on the top and bottom packages. The rejected PoP structures contribute to low pre-stack yield, wasted materials, and increased manufacturing costs.

While many advancements and/or design modifications are being taken and contemplated to inhibit warping in packages using thin or coreless substrates. Reducing warping in even smaller packages than those with thin or coreless substrates may require further advancements or design modifications.

### SUMMARY

In certain embodiments, a PoP package includes a bottom package and a top package. The bottom package may include a die coupled between an interposer layer and a redistribution layer (RDL). The die may be at least partially enclosed in an encapsulant between the interposer layer and the redistribution layer. The die may be coupled to the interposer layer with an adhesive layer. One or more terminals on the periphery of the die may couple the interposer layer to the redistribution layer. The terminals may be at least partially enclosed in the encapsulant.

One or more terminals may couple the top of the interposer layer to the bottom of a top package. The top package may be a memory package (e.g., include one or more memory die). The terminals coupling the interposer layer and the top package may be distributed anywhere on the surface of the interposer layer (e.g., the terminals are not limited to being on the periphery of the die in the bottom package). The interposer layer and the RDL in the bottom package help to inhibit warpage in the bottom package and reduce the overall thickness of the PoP package.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIGS. 1A-E depict cross-sectional representations of an embodiment of a process flow for forming a PoP package.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

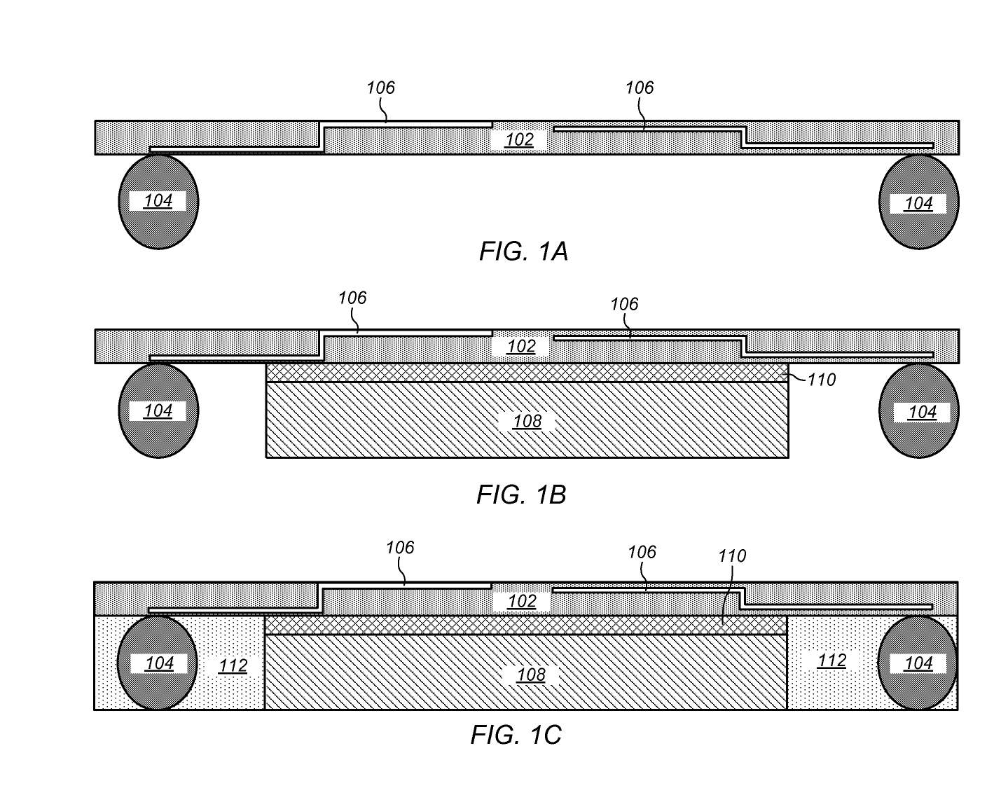

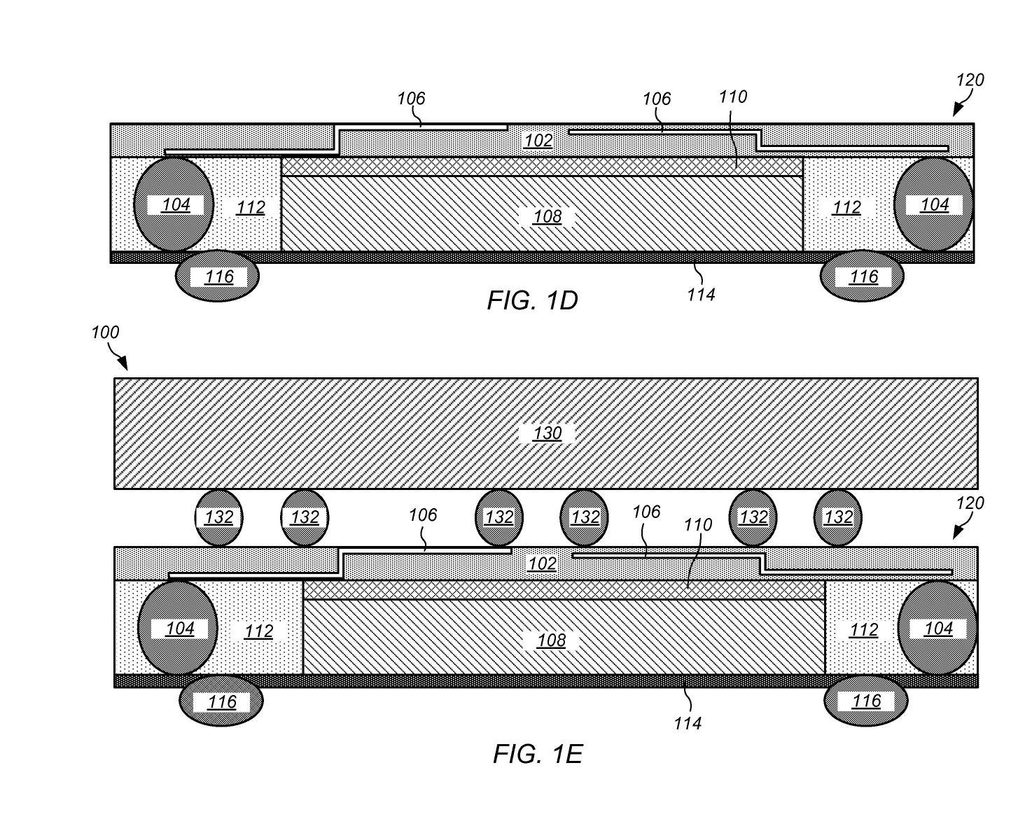

FIGS. 1A-E depict cross-sectional representations of an embodiment of a process flow for forming a PoP package. FIG. 1A depicts a cross-sectional representation of an embodiment of interposer layer 102 with terminals 104 coupled to a bottom surface (side) of the interposer layer. In certain embodiments, the interposer layer/terminal combination is provided to the process flow with terminals 104 already attached (e.g., pre-attached) to interposer layer 102. Terminals 104 may be, for example, aluminum balls or balls of another suitable conductive material. In some embodiments, terminals 104 are solder-coated or Sn-coated.

In certain embodiments, interposer layer 102 includes two active layers 106 (e.g., two active metal layers) such that the interposer layer is a 2-layer interposer layer. In some embodiments, interposer layer 102 includes more than two active layers 106. Multiple active layers 106 in interposer layer 102 may be designed to provide non-vertical routing through the interposer layer (e.g., the active layers of interposer layer are designed as if they are in a multi-layer PCB (printed circuit board)). Thus, interposer layer 102 may be designed to couple terminals that are not mirror images of each other (e.g., the terminals are not directly opposite each other on opposite sides of the interposer layer).

In certain embodiments, interposer layer 102 includes a laminate material. For example, interposer layer 102 may include BT (Bismaleimide/Triazine) laminate or any other suitable prepreg (pre-impregnated) laminate material. Active layers 106 may include conductive metal layers such as copper, aluminum, or gold. Interposer layer 102 may be formed using techniques known in the art for forming laminate materials.

After interposer layer 102 with terminals 104 attached is formed/provided, a die may be coupled to the interposer layer. FIG. 1B depicts a cross-sectional representation of an embodiment of interposer layer 102 coupled to die 108. In certain embodiments, die 108 is a processor or logic die, or die 108 is a system on a chip (“SoC”). Die 108 may be, for example, a semiconductor chip die such as a flip chip die.

Die 108 may be coupled (e.g., attached) to interposer layer 102 using known bonding techniques for die/laminate interfaces. In certain embodiments, die is coupled to interposer layer 102 with adhesive layer 110. Adhesive layer 110 may be, for example, a curable epoxy or another suitable die attach film.

After die 108 is coupled to interposer layer 102, the die and terminals 104 are at least partially encapsulated in an encapsulant coupled to the interposer layer. FIG. 1C depicts a cross-sectional representation of an embodiment of die 110 and terminals 104 encapsulated in encapsulant 112. Encapsulant 112 may be, for example, a polymer or a mold compound. In some embodiments, interposer layer 102, terminals 104, and die 108 are placed on reconstruction and encapsulant (mold) is formed over and encapsulates the terminals and the die. At least some portion of the bottom surfaces of terminals 104 and die 108 may be exposed by encapsulant 112 to allow coupling (e.g., bonding) of the terminals and the die to later formed layers in the PoP package.

After encapsulation of die 108 and terminals 104, a redistribution layer (RDL) may be formed and coupled to the die and/or the terminals to form a bottom package. FIG. 1D depicts a cross-sectional representation of an embodiment of redistribution layer (RDL) 114 coupled to die 108 and terminals 104 to form bottom package 120. RDL 114 may also be coupled to encapsulant 112. RDL 114 may include materials such as, but not limited to, PI (polyimide), PBO (polybenzoxazole), BCB (benzocyclobutene), and WPRs (wafer photo resists such as novolak resins and poly(hydroxystyrene) (PUS) available commercially under the trade name WPR including WPR-1020, WPR-1050, and WPIC-1201 (WPR is a registered trademark of JSR Corporation, Tokyo, Japan)). RDL 114 may be formed on die 108, terminals 104, and encapsulant 112 using techniques known in the art (e.g., techniques used for polymer deposition). In certain embodiments, RDL 114 includes one or more landing pads for coupling to terminals 104. For example, RDL 114 may include aluminum landing pads or solder-coated or Sn-coated aluminum landing pads for coupling to terminals 104.

After formation of RDL 114, terminals 116 may be coupled to the RDL, as shown in FIG. 1D. Terminals 116 may be used to couple bottom package 120 to a motherboard or a printed circuit board (PCB). Terminals 116 may include aluminum or another suitable conductive material. In some embodiments, terminals 116 are solder-coated or Sn-coated.

In certain embodiments, RDL 114 includes routing (e.g., wiring or connection) between die 108 and one or more of terminals 116 and/or routing between terminals 104 and one or more of terminals 116. Thus, RDL 114 allows for bonding and electrical coupling, through terminals 116, to a motherboard or PCB for die 108 and/or terminals 104 at locations away from the die and the terminals.

RDL 114 may be a relatively thin layer as compared to substrates typically used for SOC packages (e.g., bottom packages in PoP packages). For example, RDL 114 may have a thickness of less than about 50 μm (e.g., about 25 μm) while typical thin substrates have thicknesses of about 300-400 μm and coreless substrates have thicknesses in the range of about 200 μm. Thus, using RDL 114 in bottom package 120 reduces the overall thickness of the bottom package and a PoP package containing the bottom package. For example, bottom package 120 may have a thickness of about 350 gm or less.

Additionally, using interposer layer 102 on the top of bottom package 102 and RDL 114 on the bottom of the bottom package may reduce warpage problems in the bottom package. For example, interposer layer 102 and RDL 114 may have similar thermal properties (e.g., coefficient of thermal expansion (“CTE”) and/or shrinkage rate) such that the interposer layer and the RDL expand/contract at relatively similar rates to inhibit warpage in bottom package 120. In some embodiments, bottom package 120 may be flattened (e.g., using compressive force) because of the use of interposer layer 102 and RDL 114. Flattening bottom package 120 may reduce or eliminate warpage in the bottom package. Reducing warpage problems in bottom package 120 may produce a higher yield for the PoP package (e.g., reduce the number of packages rejected due to warpage problems), thereby, increasing reliability and decreasing manufacturing costs.

In certain embodiments, top package 130 is coupled to bottom package 120 to form PoP package 100, as shown in FIG. 1E. Top package 130 may be coupled to bottom package 120 using one or more terminals 132. Terminals 132 may couple with openings in interposer layer 102 (e.g., openings to active layer 106 in the interposer layer). Interposer layer 102 may be pre-formed with the openings for coupling to terminals 132 to active layer 106 (e.g., interposer layer 102, as shown in FIG. 1A, may already have the openings). Terminals 132 may be, for example, solder balls, copper pillars, or other suitable terminals for contact between top package 130 and interposer layer 102.

Top packages in typical PoP packages have terminals located around the periphery of the top package (e.g., wiring for the terminals fan out from the die). The terminals fan out so that connections can be made on the periphery of the die in the bottom package as the die in the bottom package is typically exposed above the encapsulant in the bottom package. Because terminals 132 in top package 130 are coupled to interposer layer 102 and the interposer layer substantially covers the top surface of bottom package 120 and covers die 108, terminals 132 are not limited to being located only on the periphery (e.g., the terminals may be located anywhere on the surface of the interposer layer). Thus, PoP package 100 may use a higher number of terminals 132 to couple top package 130 to bottom package 120 than typical PoP packages. The use of many more terminals 132 and the increase in the location availability for the terminals allows for more flexibility in the design of top package 130 and, thus, better integrity in PoP package 100. For example, top package 130 may have memory die of different sizes than typical PoP packages and/or the top package could have a fan in wire bond pattern instead of a fan out wire bond pattern.

Top package 130 may include a substrate and one or more die enclosed in an encapsulant. The die in top package 130 may be coupled (e.g., connected) to the substrate using, for example, one or more wire bonds. The die in top package 130 may be, for example, semiconductor chips such as wire-bond die or flip chip die. In certain embodiments, the die in top package 130 are memory die (e.g., DRAM die).

In certain embodiments, top package 130 includes memory die with a minimum layer count. For example, top package 130 may include memory die in a two layer (2L) layer count. Having a minimum layer count in top package 130 minimizes the overall thickness of PoP package 100. In certain embodiments, top package 130 has a thickness of about 450 gm. Thus, PoP package may have an overall thickness of about 800 gm if bottom package 120 has a thickness of about 350 gm. The thickness of PoP package may be reduced further by, for example, flattening of either top package 130 or bottom package 120.

In certain embodiments, top package 130 and interposer layer 102 are co-designed (e.g., layouts/routing in each are designed in connection with each other). Co-designing top package 130 and interposer layer 102 may improve and/or maximize signal integrity between the top package and the interposer layer, thus, improving performance of PoP package 100.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A semiconductor device package, comprising:
a redistribution layer;
an encapsulant above the redistribution layer;
an interposer layer above the encapsulant;
a die at least partially enclosed in the encapsulant, wherein the die is coupled to an upper surface of the redistribution layer and a lower surface of the interposer layer; and
one or more terminals coupling at least part of the interposer layer to at least part of the redistribution layer, wherein the terminals are located in the encapsulant on a periphery of the die.

2. The package of claim 1, wherein the die is coupled to the lower surface of the interposer layer with an adhesive layer.

3. The package of claim 1, further comprising a memory package coupled to the interposer layer through one or more additional terminals located on an opposite side of the interposer layer from the die.

4. The package of claim 3, wherein the additional terminals are positioned on both the periphery of the die and above the die.

5. The package of claim 3, wherein the interposer layer comprises routing that corresponds to locations of the one or more terminals coupling at least part of the interposer layer to at least part of the redistribution layer and the one or more additional terminals located on an opposite side of the interposer layer from the die.

6. The package of claim 1, further comprising one or more additional terminals coupled to a lower surface of the redistribution layer, wherein the additional terminals are configured to couple the package to a motherboard or a printed circuit board.

7. The package of claim 6, wherein the redistribution layer routes the additional terminals to the periphery of the die.

8. The package of claim 1, wherein the interposer layer comprises a two layer interposer layer.

9. A method for forming a semiconductor device package, comprising:
providing an interposer layer with one or more first terminals coupled to a first side of the interposer layer;
coupling a die to the first side of the interposer layer with the terminals located on a periphery of the die;
at least partially encapsulating the die and the terminals in an encapsulant; and
coupling a redistribution layer to the die and the terminals.

10. The method of claim 9, further comprising coupling the die to the interposer layer with an adhesive layer.

11. The method of claim 9, further comprising coupling a memory package to the interposer layer using one or more additional terminals located on a second side of the interposer layer opposite from the first side.

12. The method of claim 11, wherein the additional terminals are positioned on both the periphery of the die and above the die.

13. The method of claim 9, further comprising coupling one or more additional terminals to a lower surface of the redistribution layer, and coupling, the additional terminals to a motherboard or a printed circuit board.

14. The method of claim 13, wherein the redistribution layer routes the additional terminals to the periphery of the die.

15. A semiconductor device package, comprising:
a mold material positioned between an interposer layer and a redistribution layer;
a die at least partially enclosed in the mold material, wherein the die is coupled to the interposer layer and the redistribution layer; and
one or more terminals coupling the interposer layer to the redistribution layer, wherein the terminals are located in the mold material on a periphery of the die.

16. The package of claim 15, wherein the die is coupled to the interposer layer with an adhesive layer.

17. The package of claim 15, further comprising one or more additional terminals located on an opposite side of the interposer layer from the die, wherein the additional terminals are configured to couple the package to a memory package.

18. The package of claim 17, wherein the additional terminals are positioned on both the periphery of the die and above the die.

19. The package of claim 15, wherein the redistribution layer comprises electrical routing that couples the die to one or more additional terminals on the periphery of the die.

20. The package of claim 15, wherein the interposer layer comprises a two layer interposer layer.
